(19) United States
(12) Patent Application Publication
(10) Pub. No.: US 2008/0182363 A1
(43) Pub. Date: Jul. 31, 2008

(54) METHOD FOR FORMING A MICROELECTRONIC ASSEMBLY INCLUDING ENCAPSULATING A DIE USING A SACRIFICIAL LAYER

(75) Inventors: Craig S. Amrine, Tempe, AZ (US); Owen R. Fay, Gilbert, AZ (US); Lizabeth Ann Keser, Chandler, AZ (US); Kevin R. Lish, Higley, AZ (US); William H. Lytle, Chandler, AZ (US); Chandrasekaram Ramiah, Phoenix, AZ (US); Jerry L. White, Glendale, AZ (US)

Correspondence Address: INGRASSIA FISHER & LORENZ, P.C. (FS), 7010 E. COCHISE ROAD, SCOTTSDALE, AZ, 85253, US

(73) Assignee: FREESCALE SEMICONDUCTOR, INC., Austin, TX (US)

(21) Appl. No.: 11/669,625

(22) Filed: Jan. 31, 2007

(51) Int. Cl. H01L 21/56

(52) U.S. Cl. 438/118; 257/E21.502

(57) ABSTRACT

A method for forming a microelectronic assembly is provided. A carrier substrate (30) is provided. A sacrificial layer (38) is formed over the carrier substrate. A polymeric layer (40), including a polymeric tape (42) and a polymeric layer adhesive (44), is formed over the sacrificial layer. The polymeric layer adhesive is between the sacrificial layer and the polymeric tape. A microelectronic die (52), having an integrated circuit formed therein, is placed on the polymeric layer. The microelectronic die is encapsulated with an encapsulation material (54) to form an encapsulated structure (58). The polymeric layer and the encapsulated structure are separated from the carrier substrate. The separating of the polymeric layer and the encapsulated structure includes at least partially deteriorating the sacrificial layer.

### TECHNICAL FIELD

The present invention generally relates to a microelectronic assembly and a method for forming a microelectronic assembly, and more particularly relates to a method for encapsulating a die using a sacrificial layer.

### BACKGROUND

Integrated circuits are formed on semiconductor substrates (or wafers). The wafers are then sawn into microelectronic die (or “dice”), or semiconductor chips, with each die carrying a respective integrated circuit. Each semiconductor chip is connected to a package or carrier substrate using either wire bonding or “flip-chip” connections. The packaged chip is then typically mounted to a circuit board, or motherboard, before being installed in a system, such as an electronic or a computing system.

Recently, technologies have been developed which may reduce the need for conventional package substrates. One technology involves embedding the microelectronic die in substrates, or panels, and forming electrical connections from a “device” surface of the die to other portions of the panels. The panels are often formed by attaching one side of a piece of double-sided tape to a carrier, or support, substrate, placing multiple die on the opposing side of the double-sided tape, and dispensing an epoxy over the die. After the epoxy is at least partially cured, the tape and the panel are removed from the carrier substrate, often using a solvent to dissolve the adhesive between the carrier substrate and the tape. Porous carrier substrates are often used so that the solvent will seep through the substrate to contact and dissolve the adhesive.

After the tape is removed, undissolved residue from the adhesive often remains on the carrier substrates. As a result, if the carrier substrates are to be reused, the carrier substrates may have to be cleaned (i.e., scrubbed) to prevent any of the residue from clogging the pores and inhibiting the solvent from seeping through. This cleaning process increases the costs, as well as the time required, to manufacture the panels.

Accordingly, it is desirable to provide a method for encapsulating a microelectronic die that reduces the amount of residue left on the carrier substrate after the double-sided tape is removed. Additionally, other desirable features and characteristics of the invention will become apparent from the subsequent detailed description and the appended claims, taken in conjunction with the accompanying drawings and the foregoing technical field and background.

### BRIEF DESCRIPTION OF THE DRAWINGS

The various embodiments will hereinafter be described in conjunction with the following drawings, wherein like numerals denote like elements, and

FIG. 1 is a cross-sectional side view of a carrier substrate;

FIG. 2 is a cross-sectional side view of the carrier substrate of FIG. 1 with a sacrificial layer formed thereon;

FIG. 3 is a cross-sectional side view of the carrier substrate of FIG. 2 with a polymeric layer formed over the sacrificial layer;

FIG. 4 is a cross-sectional side view of the carrier substrate of FIG. 3 with a mold frame positioned over the polymeric layer;

FIG. 5 is a cross-sectional side view of the carrier substrate of FIG. 4 with microelectronic die placed on the polymeric layer;

FIG. 6 is a top plan view of the carrier substrate of FIG. 5;

FIG. 7 is a cross-sectional side view of the carrier substrate of FIG. 5 with an encapsulation material deposited over the microelectronic die;

FIG. 8 is a cross-sectional side view of the carrier substrate of FIG. 7 undergoing a heating process;

FIG. 9 is a cross-sectional side view of the carrier substrate after undergoing the heating process shown in FIG. 8;

FIG. 10 is a cross-sectional side view of the carrier substrate of FIG. 9 illustrating the encapsulation material undergoing a grinding process;

FIG. 11 is a cross-sectional side view of the carrier substrate of FIG. 10 undergoing a second heating process;

FIG. 12 is a cross-sectional side view of the carrier substrate of FIG. 11 illustrating the polymeric layer and the encapsulation material being separated from the carrier substrate;

FIG. 13 is a cross-sectional side view of the carrier substrate of FIG. 12 illustrating the encapsulation material, along with the microelectronic die, being separated from the polymeric layer;

FIG. 14 is a cross-sectional side view of a integrated circuit package formed from the encapsulation material and microelectronic die of FIG. 13;

FIG. 15 is a cross-sectional side view of a carrier substrate with a sacrificial layer, polymeric layer, and encapsulation material formed thereon, according to an alternative embodiment of the present invention;

FIG. 16 is a cross-sectional side view of the carrier substrate of FIG. 15 undergoing a solvent exposure; and

FIG. 17 is a cross-sectional side view of the carrier substrate of FIG. 16 illustrating the polymeric layer and encapsulation material being separated from the carrier substrate.

### DETAILED DESCRIPTION

The following detailed description is merely exemplary in nature and is not intended to limit the application and uses of the various embodiments. Furthermore, there is no intention to be bound by any expressed or implied theory presented in the preceding technical field, background, and brief summary, or the following detailed description. It should also be noted that FIGS. 1-17 are merely illustrative and may not be drawn to scale.

FIG. 1 to FIG. 17 illustrate methods for forming a microelectronic assembly, according to various embodiments. In general, a carrier substrate is provided, and a sacrificial layer is formed over the carrier substrate. A polymeric layer, including a polymeric tape and a polymeric layer adhesive, is formed over the sacrificial layer with the polymeric layer adhesive being between the sacrificial layer and the polymeric tape. A microelectronic die, having an integrated circuit formed therein, is placed on the polymeric layer. The microelectronic die is encapsulated with an encapsulation material to form an encapsulated structure. The polymeric layer and the encapsulated structure are separated from the carrier substrate. The separating of the polymeric layer and the encapsulated structure includes at least partially deteriorating the sacrificial layer.

In one embodiment, the sacrificial layer includes a thermally-degradable adhesive. The thermally-degradable adhesive may be formed on a thermal release tape that is placed on the carrier substrate. In another embodiment, the sacrificial layer includes a solvent soluble adhesive formed on the carrier substrate.

Referring to FIG. 1, there is illustrated a portion of a carrier (or support) substrate 30. In one embodiment, the carrier substrate 30 is made of glass and has a thickness 32 of, for example, between 1 and 7 mm. The carrier substrate 30 may be, for example, circular, rectangular, or square in shape with a width (i.e., diameter or side length) of approximately 200 or 450 mm. It should be understood that although the following process steps may be shown as being performed on only a portion of the carrier substrate 30, each of the steps may be performed on substantially the entire carrier substrate 30, simultaneously.

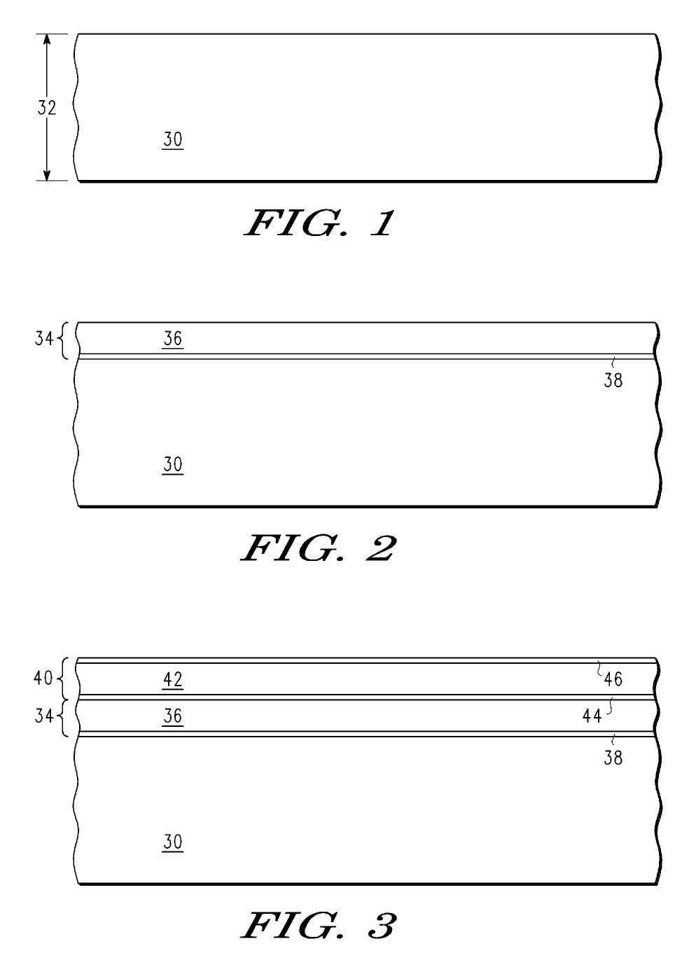

As illustrated in FIG. 2, a thermal release layer 34 is first placed, or formed, on an upper surface of the carrier substrate 30. The thermal release layer 34 includes a thermal release tape 36 and a layer of thermally-degradable adhesive 38 (i.e., a “sacrificial” adhesive) formed on the thermal release tape 36. As shown, the thermal release layer 34 is oriented on the carrier substrate 30 so that the thermally-degradable adhesive 38 is between the carrier substrate 30 and the thermal release tape 36. Although not specifically illustrated, in one embodiment, the thermal release tape 36 has a thickness of, for example, between 0.5 and 1 mm, and the thermally-degradable adhesive 38 has a thickness of, for example, between 50 and 75 microns (μm). The particular thermally-degradable adhesive 38 may have a “breakdown” temperature of, for example, between 100 and 175° C. That is, the thermally-degradable adhesive 38 may begin to lose adhesion between 100 and 175° C. As will be discussed below, the thermally-degradable adhesive 38 and/or the thermal release tape 36 may serve as a sacrificial layer for subsequent processing steps. Although in the depicted embodiment the thermal release layer 34 includes both the thermal release tape 36 and the thermally-degradable adhesive 38, in another embodiment, the thermal release layer 34 may utilize the thermally-degradable adhesive 38 without the thermal release tape 36.

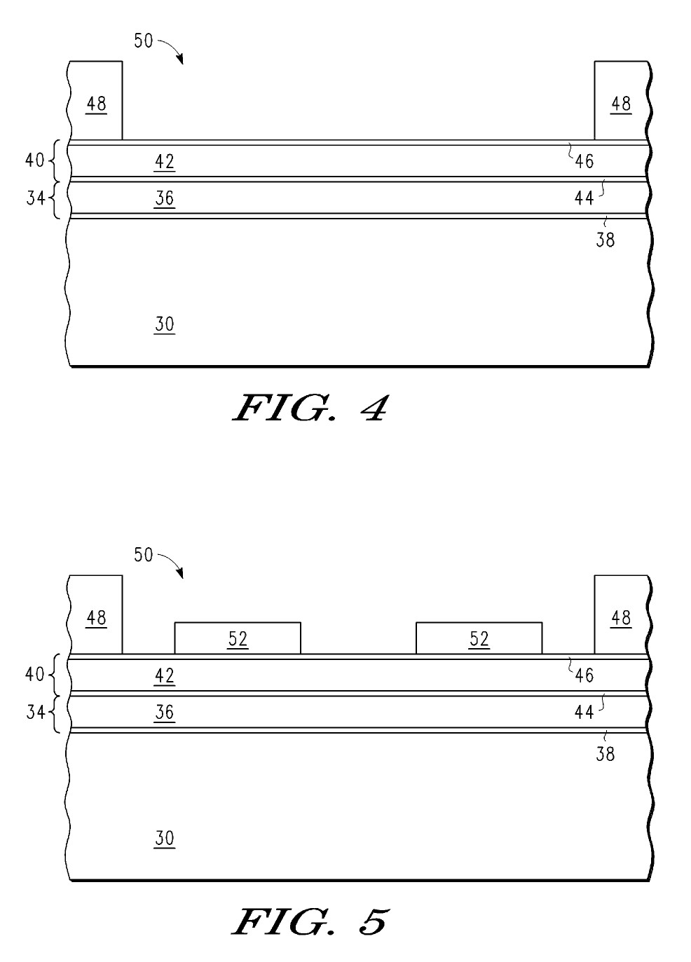

Referring to FIG. 3, a polymeric layer 40 is then formed over the thermal release layer 34, which completely separates the polymeric layer 40 from the carrier substrate 30. The polymeric layer 40 includes a polymeric tape 42, a first polymeric layer adhesive 44, and a second polymeric layer adhesive 46. In the example shown, the polymeric layer 40 is arranged so that the first polymeric layer adhesive 44 is between the thermal release tape 36 and the polymeric tape 42 (i.e., on a lower side of the polymeric tape 42) and the second polymeric layer adhesive 46 is on an upper, or exposed, side of the polymeric tape 42. Although not shown, the polymeric tape 42 has a thickness of, for example, between 0.5 and 1 mm, and the first and second polymeric layer adhesives 44 and 46 have a thickness of, for example, between 50 and 75 μm. In one embodiment, the polymeric tape 42 is made of polyimide, the first polymeric layer adhesive 44 is an acrylic adhesive, and the second polymeric layer adhesive 46 is a silicone adhesive, as is commonly understood. In another embodiment, the second polymeric layer adhesive 46 is a silicone adhesive similar to the first polymeric layer adhesive 44.

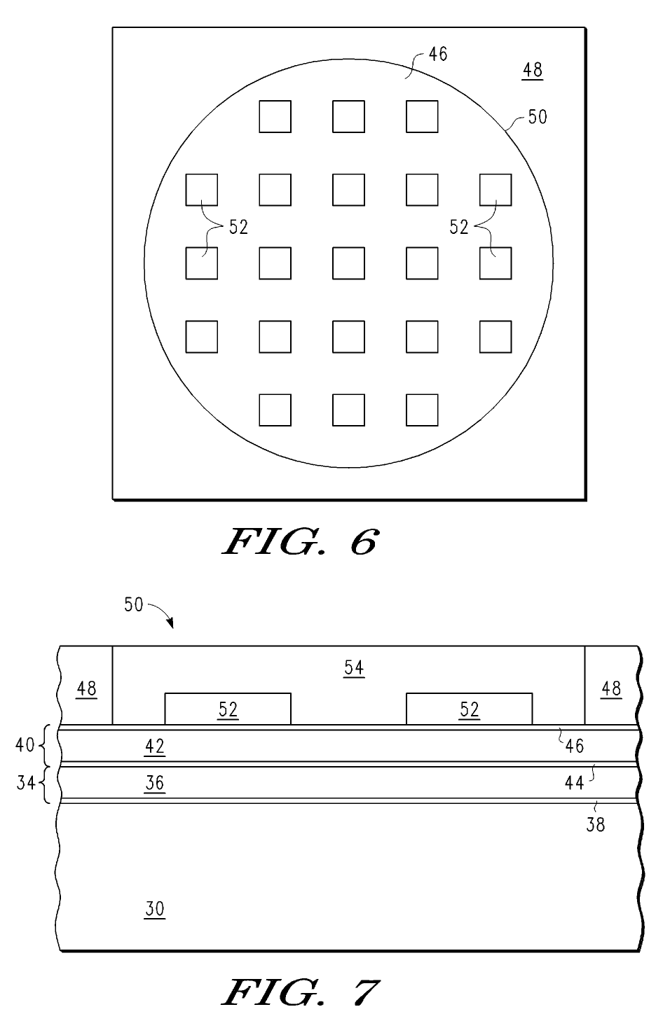

As shown schematically in FIG. 4, a mold frame 48 is then placed over the polymeric layer 40. The mold frame 48 has an opening 50 at a central portion thereof that lies over a central, exposed portion of the carrier substrate 30. Referring ahead to FIG. 6, the opening 50 may be similar in size and shape to the entire carrier substrate 30, as will be appreciated by one skilled in the art.

Referring to FIG. 5 in combination with FIG. 6, multiple microelectronic die 52 are then placed within the opening 50 of the mold frame 48 and onto the second polymeric layer adhesive 46. In one embodiment, each die 52 includes a substrate made of a semiconductor material, such as gallium arsenide (GaAs), gallium nitride (GaN), or silicon (Si) with an integrated circuit formed thereon (or therein). In the depicted embodiment, the die 52 are substantially square (or rectangular) with a side length of, for example, between 5 and 20 mm and a thickness of, for example, between 75 and 800 μm. Referring specifically to FIG. 6, the die 52 are evenly spaced within the opening 50 of the mold frame 48. As will be appreciated by one skilled in the art, in one embodiment, the placement of the die 52 may be controlled to account for physical changes in the various components of the assembly shown, such as expansion and/or compression due to variations in the coefficients of thermal expansion (CTE) of the various materials used.

Next, as illustrated in FIG. 7, an encapsulation material 54 is deposited (or formed) over the microelectronic die 52 and on the exposed portions of the second polymeric layer adhesive 46 within the opening 50 of the mold frame 48. Although not shown, the encapsulation material 54 may be deposited to have a depth (or thickness) of, for example, approximately 0.65 mm, which may be similar to a thickness of the mold frame 48 (as measured over the second polymeric layer adhesive 46). In one embodiment, the encapsulation material is a silica-filled epoxy with a final cure temperature of, for example, between 140 and 150° C. and is dispensed into the opening 50 with a syringe and robotic needle, as is commonly understood. Other embodiments may use other types of encapsulation materials and other processes to deposit the encapsulation material 54, such as screen printing, extrusion coating, transfer molding, ejection molding, and “glob top.”

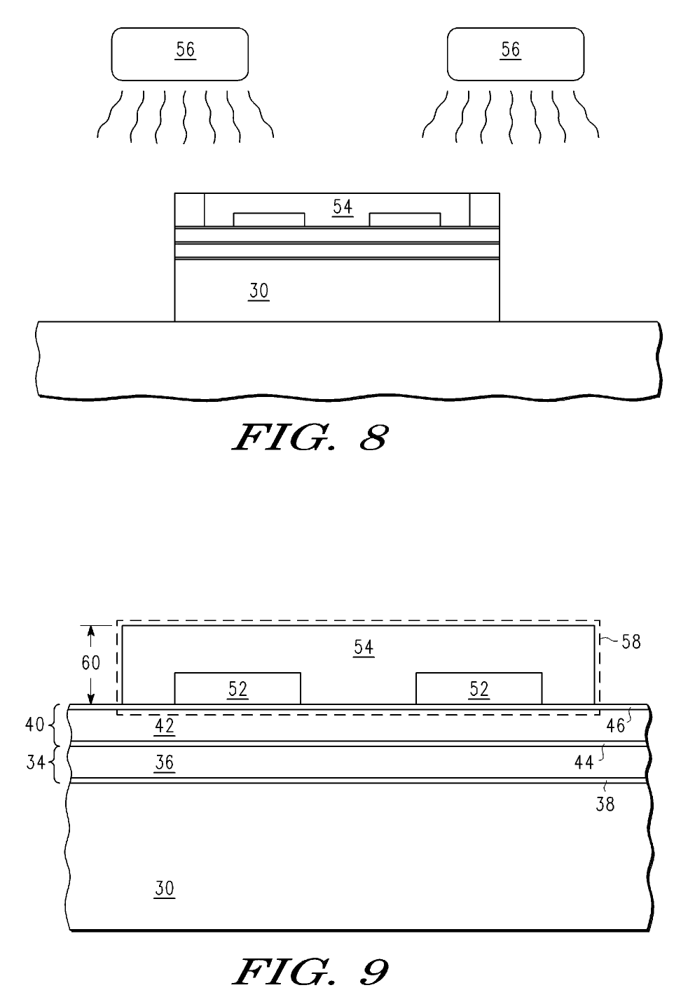

As shown in FIG. 8, the carrier substrate 30, along with the various components formed thereon, are then heated or “baked” in, for example, an oven with heating elements 56, as is commonly understood. In one embodiment, the carrier substrate 30 is baked at approximately 100° C. (i.e., a partial cure temperature) for 60 minutes. As such, the heating process depicted in FIG. 8 only partially cures (e.g., 80% cure) the encapsulation material 54. Additionally, because the partial cure temperature is below the thermal breakdown temperature of the thermally-degradable adhesive 38, a strong adhesive bond remains between the carrier substrate 30 and the thermal release tape 36 (shown in FIG. 7) after the heating process described above.

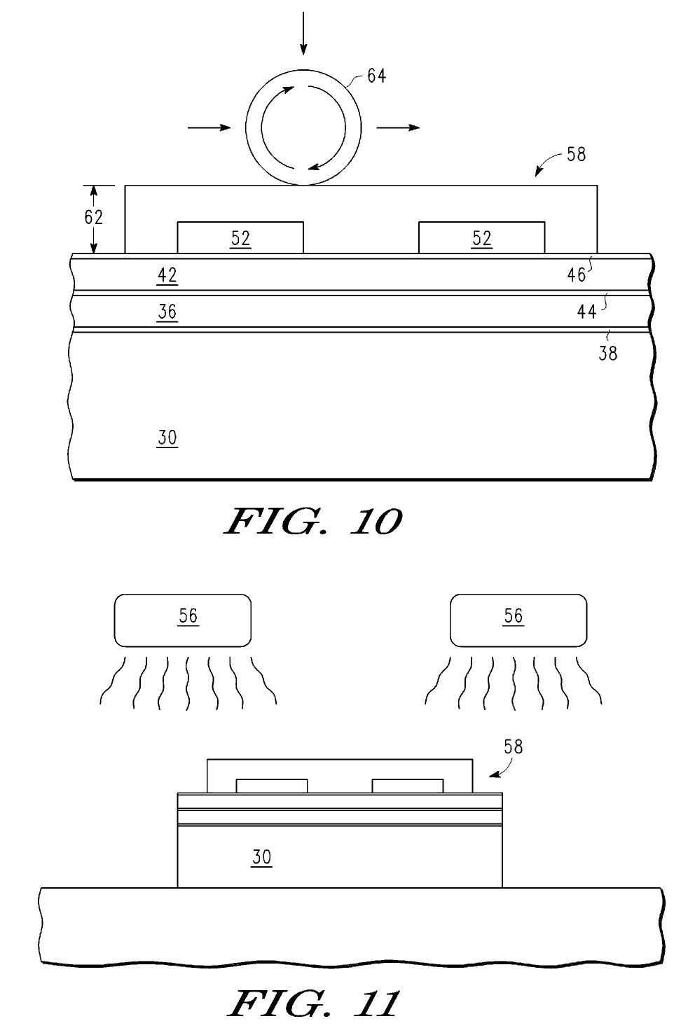

Referring to FIG. 9, the mold frame 48 is then removed. After the partial cure described above, the encapsulation material becomes partially rigid and forms an encapsulated structure (or device panel) 58. The encapsulated structure 58 has an initial thickness 60 similar to the depth of the encapsulation material 54 and includes the microelectronic die 52 embedded therein. As illustrated in FIG. 10, an exposed surface of the encapsulation structure 58 then undergoes a grinding (and/or polishing and/or abrasion) process to reduce the thickness of the encapsulated structure 58 to a reduced, or “thinned,” thickness 62. In the depicted embodiment, the grinding process is performed using a polishing or grinding head (or polishing element) 64 that is placed into contact with and pressed against the encapsulated structure 58 while being rotated and moved across the exposed surface of the encapsulated structure 58.

Next, as shown in FIG. 11, the carrier substrate 30 undergoes a second heating process. The second heating process may be at a temperature greater than or equal to the breakdown temperature of the thermally-degradable adhesive 38 and the final cure temperature of the encapsulation material 54, such as between 120 and 155° C. The second bake may take place in an oven and have a duration of, for example, between 10 and 90 minutes.

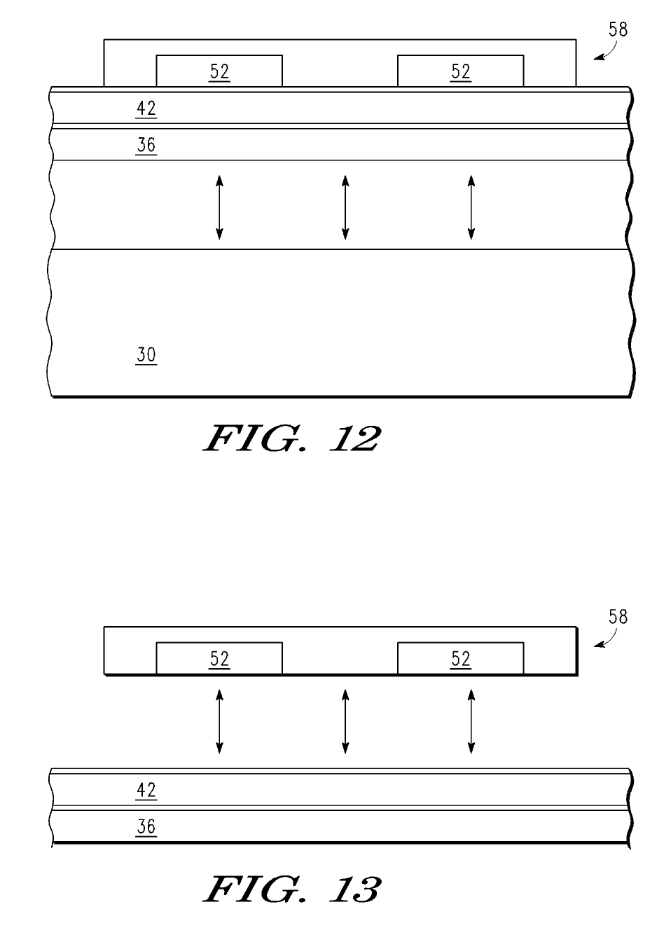

Referring to FIG. 12, the carrier substrate 30 is then de-bonded from the thermal release tape 36. The second bake may cause the thermally-degradable adhesive to deteriorate such that the thermal release tape 36 cleanly separates from the carrier substrate 30. Additionally, the second bake may cure the encapsulation material 54 within the encapsulated structure 58 such that the carrier substrate 30 is no longer required to provide support for the encapsulated structure 58 during subsequent processing steps. Because the thermally-degradable adhesive 38 (as shown in FIG. 7), as well as the thermal release tape 36, is positioned between the carrier substrate 30 and the first polymeric layer adhesive 44, substantially no residue from the first polymeric layer adhesive 44 remains on the carrier substrate 30 after the thermal release tape 36 and the polymeric tape 42 are removed from the carrier substrate 30.

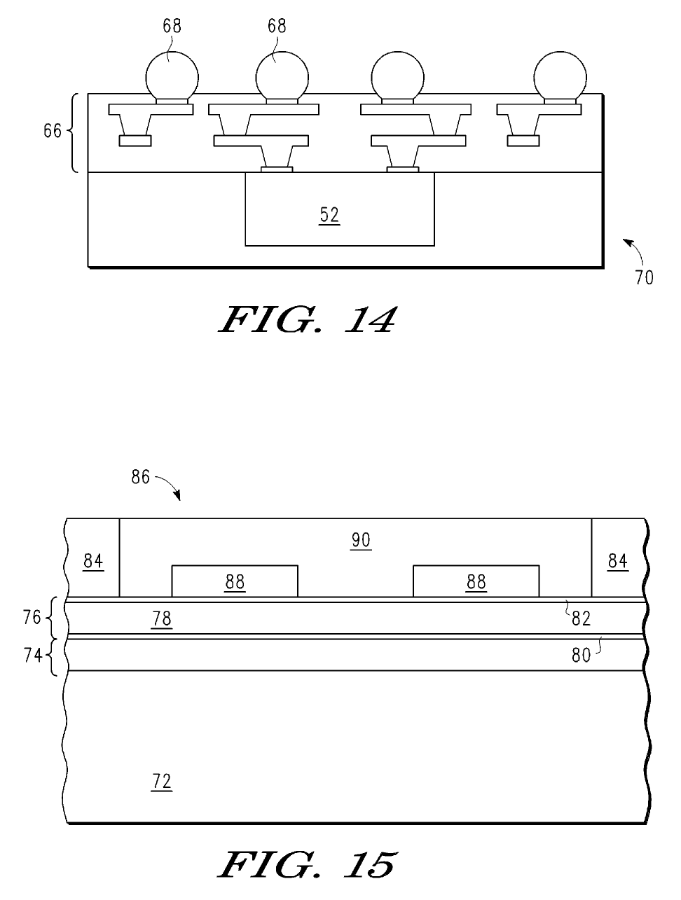

Referring to FIG. 13, the polymeric tape 42 and the thermal release tape 36 are then peeled from the encapsulated structure 58. As shown in FIG. 14, after final processing steps, a build-up layer 66, including various insulating layers and conductive traces, and contact formations (e.g., solder balls) 68 may be formed on a front side of the encapsulated structure 58. The encapsulated structure 58 may then be sawed into individual packages 70, with each package 70 carrying a respective microelectronic die 52, or multiple die 52. The individual packages 70 may then be installed into various electronic and/or computing systems.

FIG. 15 illustrates a carrier substrate 72 and other components, similar to those shown in FIG. 7, according to another embodiment of the present invention, in which a solvent soluble adhesive is used as the sacrificial layer. In the example, illustrated in FIG. 15, the carrier substrate is made of a porous material that allows a solvent to pass therethrough. In one embodiment, the porous material is a composite material of aluminum oxide embedded in a glass matrix. Other suitable materials include metals, ceramics, plastics, polymers, and combinations thereof.

Still referring to FIG. 15, formed on, or over, the carrier substrate 72 are a sacrificial layer 74 and a polymeric layer 76, which is completely separated from the carrier substrate 72 by the sacrificial layer 74. In one embodiment, the sacrificial layer 74 is layer of solvent soluble adhesive, such as a rosin-based thermoplastic adhesive. One example of such an adhesive is GENTAK 230, which is available from General Chemical of Parsippany, N.J., U.S.A. Although not illustrated, the sacrificial layer 74 may be coated onto the carrier substrate 72 by, for example, “spin-coating,” as is commonly understood.

The polymeric layer 76 is similar to the polymeric layer 40 shown in FIG. 3 and includes a layer of polymeric tape 78, a first polymeric layer adhesive 80, and a second polymeric layer adhesive 82. In the example shown, the polymeric layer 76 is arranged so that the first polymeric layer adhesive 80 is between the sacrificial layer 74 and the polymeric tape 78 (i.e., on a lower side of the polymeric tape 78), and the second polymeric layer adhesive 82 is on an upper, or exposed, side of the polymeric tape 78.

Also similar to the embodiment shown in FIG. 7, a mold frame 84 with an opening 86 is positioned over the polymeric layer 76, microelectronic die 88 are placed on the exposed portion of the second polymeric layer adhesive 82, and an encapsulation material 90 is deposited over the die 88.

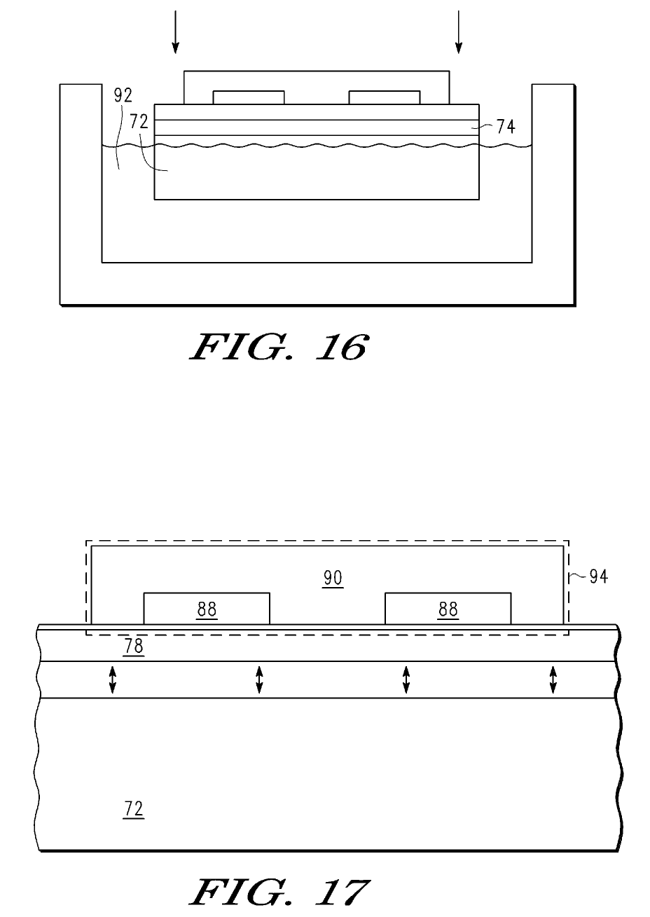

Referring to FIG. 16, after the carrier substrate 72 undergoes a heating process, which may be similar to the one shown in FIG. 8 and described above, the mold frame 84 is removed, and the carrier substrate 72 is at least partially submerged in a solvent 92 in which the solvent soluble adhesive of the sacrificial layer 74 is soluble. In one embodiment, the carrier substrate 72 is soaked in the solvent 92 for a duration of, for example, between 30 and 120 minutes. Because the porosity of the carrier substrate 72, the solvent seeps through the carrier substrate 72 to contact the entire sacrificial layer 74. As such, the sacrificial layer 74 is dissolved. It should be understood that while the carrier substrate 72 is exposed to the solvent 92, the first polymeric layer adhesive 80 may also be at least partially dissolved.

As shown in FIG. 17, the carrier substrate 72 is then removed from the solvent, and the polymeric tape 78 and an encapsulated structure 94 (formed from the encapsulation material 90 and the microelectronic die 88) are removed from the carrier substrate 72. Because the sacrificial layer 74, before being dissolved, is positioned between the carrier substrate 72 and the first polymeric layer adhesive 80 (shown in FIG. 15), substantially no residue from the first polymeric layer adhesive 80 remains on carrier substrate 72.

The polymeric tape 78 may then be removed from the encapsulated structure 94, and the encapsulated structure may be separated into individual packages, in manner similar to that shown in FIGS. 13 and 14 and described above. The packages may then be installed in various electronic and computing systems.

One advantage of the methods described above is that because the sacrificial layer separates the carrier substrate from the adhesives on the polymeric tape, the likelihood that any residue from the adhesives on the polymeric tape will be left on the carrier substrate after the polymeric tape is removed, is greatly reduced. Thus, when a porous carrier substrate is used, the probability that any residue from the adhesives will clog any of the pores is minimized. Additionally, the use of the thermally-degradable adhesive allows for a non-porous material (e.g., glass) to be used. Therefore, the frequency with which the carrier substrate is cleaned may be reduced, which reduces manufacturing costs and increases the rate at which devices may be formed.

The invention provides a method for forming a microelectronic assembly. A carrier substrate is provided. A sacrificial layer is formed over the carrier substrate. A polymeric layer, including a polymeric tape and a polymeric layer adhesive, is formed over the sacrificial layer. The polymeric layer adhesive is between the sacrificial layer and the polymeric tape. A microelectronic die, having an integrated circuit formed therein, is placed on the polymeric layer. The microelectronic die is encapsulated with an encapsulation material to form an encapsulated structure. The polymeric layer and the encapsulated structure are separated from the carrier substrate. The separating of the polymeric layer and the encapsulated structure includes at least partially deteriorating the sacrificial layer.

The sacrificial layer may include a thermally-degradable adhesive having a breakdown temperature. The at least partially deteriorating the sacrificial layer may include heating the sacrificial layer to a first temperature. The first temperature may be greater than or equal the breakdown temperature of the thermally-degradable adhesive. The encapsulation material may have a final cure temperature that is greater than or equal to the first temperature.

The method may also include heating the encapsulation material to a second temperature, which may be less than the final cure temperature, to partially cure the encapsulation material and grinding a surface of the encapsulated structure to reduce a thickness of the encapsulation structure from a first thickness to a second thickness. The grinding of the surface of the encapsulated structure may occur after the heating of the encapsulation material to the second temperature and before the heating of the sacrificial layer to the first temperature.

The carrier substrate may include glass and the sacrificial layer may also include a thermal release tape. The thermally-degradable adhesive may be between the carrier substrate and the thermal release tape. The polymeric layer may include a second polymeric layer adhesive on a side of the polymeric tape adjacent to the microelectronic die.

The sacrificial layer may include a solvent soluble adhesive. The at least partially deteriorating the sacrificial layer may include exposing the sacrificial material to a solvent in which the solvent soluble adhesive dissolves.

The invention also provides a method for forming a microelectronic assembly. A carrier substrate is provided. A sacrificial layer is formed on the carrier substrate. A polymeric layer is formed on the sacrificial layer. The polymeric layer includes a polymeric tape, a first polymeric layer adhesive, and a second polymeric layer adhesive. The first polymeric layer adhesive is on a side of the polymeric tape adjacent to the sacrificial layer. The second polymeric layer adhesive is on a side of the polymeric tape opposite the sacrificial layer. A microelectronic die is placed on the second polymeric layer adhesive. The microelectronic die is encapsulated with an encapsulation material to form an encapsulated structure. The polymeric layer and the encapsulated structure are separated from the carrier substrate. The separating includes at least partially deteriorating the sacrificial layer.

The sacrificial layer may include a sacrificial adhesive. The sacrificial layer may also include a thermal release tape. The sacrificial adhesive may be a thermally-degradable adhesive formed on the thermal release tape. The forming of the sacrificial layer may include placing the thermal release tape on the carrier substrate with the thermally-degradable adhesive between the carrier substrate and the thermal release tape.

The method may also include heating the thermally-degradable adhesive and the encapsulation material to a first temperature, which may be less than a breakdown temperature of the thermally-degradable adhesive and less than a final cure temperature of the encapsulation material, to partially cure the encapsulation material and grinding a surface of the encapsulated structure to reduce a thickness of the encapsulation structure from a first thickness to a second thickness after the heating the thermally-degradable adhesive and the encapsulation material to the first temperature.

The at least partially deteriorating the sacrificial layer may include heating the thermally-degradable adhesive and the encapsulation material to a second temperature after the grinding of the surface of the encapsulated structure. The second temperature may be greater than or equal to the breakdown temperature of the thermally-degradable adhesive and the final cure temperature of the encapsulation material.

The sacrificial adhesive may be a solvent soluble adhesive. The forming of the sacrificial layer may include coating the carrier substrate with the solvent soluble adhesive.

The invention may further provide a method for forming a microelectronic assembly. A carrier substrate is provided. A thermally-degradable adhesive, having a breakdown temperature, is formed on the carrier substrate. A microelectronic die, having an integrated circuit formed therein, is placed over the thermally-degradable adhesive. The microelectronic die is encapsulated with an encapsulation material, having a final cure temperature, to form an encapsulated structure. The thermally-degradable adhesive and the encapsulation material are heated to a first temperature, which is less than the breakdown temperature of the thermally-degradable adhesive and less than the final cure temperature of the encapsulation material, to partially cure the encapsulation material. A surface of the encapsulated structure is ground to reduce a thickness of the encapsulated structure from a first thickness to a second thickness after the heating the thermally-degradable adhesive and the encapsulation material to the first temperature. The encapsulated structure is separated from the carrier substrate. The separating may include heating the thermally-degradable adhesive and the encapsulation material to a second temperature being greater than or equal to the breakdown temperature of the thermally-degradable adhesive and greater than or equal to the final cure temperature of the encapsulation material.

The carrier substrate may be made of glass. The forming the thermally-degradable adhesive may include placing a thermal release tape on the carrier substrate. The thermally-degradable adhesive may be formed on the thermal release tape. The method may also include placing a double-sided polymeric tape on the thermal release tape, and the microelectronic die may be placed on the double-sided polymeric tape.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for forming a microelectronic assembly comprising:
providing a carrier substrate;
forming a sacrificial layer over the carrier substrate;
forming a polymeric layer over the sacrificial layer, the polymeric layer comprising a polymeric tape and a polymeric layer adhesive formed on the polymeric tape, the polymeric layer adhesive being between the sacrificial layer and the polymeric tape;
placing a microelectronic die, having an integrated circuit formed therein, on the polymeric layer;
encapsulating the microelectronic die with an encapsulation material to form an encapsulated structure; and
separating the polymeric layer and the encapsulated structure from the carrier substrate, the separating comprising at least partially deteriorating the sacrificial layer.

2. The method of claim 1, wherein the sacrificial layer comprises a thermally-degradable adhesive having a breakdown temperature.

3. The method of claim 2, wherein the at least partially deteriorating the sacrificial layer comprises heating the sacrificial layer to a first temperature being greater than or equal the breakdown temperature of the thermally-degradable adhesive.

4. The method of claim 3, wherein the encapsulation material has a final cure temperature that is greater than or equal to the first temperature.

5. The method of claim 4, further comprising:
heating the encapsulation material to a second temperature to partially cure the encapsulation material, the second temperature being less than the final cure temperature; and
grinding a surface of the encapsulated structure to reduce a thickness of the encapsulated structure from a first thickness to a second thickness.

6. The method of claim 5, wherein the grinding of the surface of the encapsulated structure occurs after the heating of the encapsulation material to the second temperature and before the heating of the sacrificial layer to the first temperature.

7. The method of claim 6, wherein the carrier substrate comprises glass and the sacrificial layer further comprises a thermal release tape, and wherein the thermally-degradable adhesive is between the carrier substrate and the thermal release tape.

8. The method of claim 7, wherein the polymeric layer comprises a second polymeric layer adhesive on a side of the polymeric tape adjacent to the microelectronic die.

9. The method of claim 1, wherein the sacrificial layer comprises a solvent soluble adhesive.

10. The method of claim 9, wherein the at least partially deteriorating the sacrificial layer comprises exposing the sacrificial layer to a solvent in which the solvent soluble adhesive dissolves.

11. A method for forming a microelectronic assembly comprising:
providing a carrier substrate;
forming a sacrificial layer on the carrier substrate;
forming a polymeric layer on the sacrificial layer, the polymeric layer comprising a polymeric tape, a first polymeric layer adhesive, and a second polymeric layer adhesive, the first polymeric layer adhesive being on a side of the polymeric tape adjacent to the sacrificial layer and the second polymeric layer adhesive being on a side of the polymeric tape opposite the sacrificial layer;
placing a microelectronic die on the second polymeric layer adhesive, encapsulating the microelectronic die with an encapsulation material to form an encapsulated structure; and
separating the polymeric layer and the encapsulated structure from the carrier substrate, the separating comprising at least partially deteriorating the sacrificial layer.

12. The method of claim 11, wherein the sacrificial layer comprises a sacrificial adhesive.

13. The method of claim 12, wherein the sacrificial layer further comprises a thermal release tape, the sacrificial adhesive is a thermally-degradable adhesive formed on the thermal release tape, and the forming of the sacrificial layer comprises placing the thermal release tape on the carrier substrate with the thermally-degradable adhesive between the carrier substrate and the thermal release tape.

14. The method of claim 13, further comprising:
heating the thermally-degradable adhesive and the encapsulation material to a first temperature to partially cure the encapsulation material, the first temperature being less than a breakdown temperature of the thermally-degradable adhesive and less than a final cure temperature of the encapsulation material; and
grinding a surface of the encapsulated structure to reduce a thickness of the encapsulated structure from a first thickness to a second thickness after the heating the thermally-degradable adhesive and the encapsulation material to the first temperature.

15. The method of claim 14, wherein the at least partially deteriorating the sacrificial layer comprises heating the thermally-degradable adhesive and the encapsulation material to a second temperature after the grinding of the surface of the encapsulated structure, the second temperature being greater than or equal to the breakdown temperature of the thermally-degradable adhesive and the final cure temperature of the encapsulation material.

16. The method of claim 12, wherein the sacrificial adhesive is a solvent soluble adhesive and the forming of the sacrificial layer comprises coating the carrier substrate with the solvent soluble adhesive.

17. A method for forming a microelectronic assembly comprising:
providing a carrier substrate;
forming a thermally-degradable adhesive, having a breakdown temperature, on the carrier substrate;
placing a microelectronic die, having an integrated circuit formed therein, over the thermally-degradable adhesive;
encapsulating the microelectronic die with an encapsulation material, having a final cure temperature, to form an encapsulated structure;
heating the thermally-degradable adhesive and the encapsulation material to a first temperature being less than the breakdown temperature of the thermally-degradable adhesive and less than the final cure temperature of the encapsulation material to partially cure the encapsulation material;
grinding a surface of the encapsulated structure to reduce a thickness of the encapsulated structure from a first thickness to a second thickness after the heating the thermally-degradable adhesive and the encapsulation material to the first temperature; and
separating the encapsulated structure from the carrier substrate, the separating comprising heating the thermally-degradable adhesive and the encapsulation material to a second temperature being greater than or equal to the breakdown temperature of the thermally-degradable adhesive and greater than or equal to the final cure temperature of the encapsulation material.

18. The method of claim 17, wherein the carrier substrate is made of glass.

19. The method of claim 18, wherein the forming the thermally-degradable adhesive comprises placing a thermal release tape on the carrier substrate, the thermally-degradable adhesive being formed on the thermal release tape.

20. The method of claim 19, further comprising placing a double-sided polymeric tape on the thermal release tape and wherein the microelectronic die is placed on the double-sided polymeric tape.
